(19) United States
(12) Patent Application Publication
(10) Pub. No.: US 2013/0156061 A1
(43) Pub. Date: Jun. 20, 2013

(54) Arrangement for Generating Fast Wavelength-Switched Optical Signal

(71) Applicants: Leif Johansson, Goleta, CA (US); Jonathon Barton, Santa Barbara, CA (US); Milan Mashanovitch, Santa Barbara, CA (US)

(72) Inventors: Leif Johansson, Goleta, CA (US); Jonathon Barton, Santa Barbara, CA (US); Milan Mashanovitch, Santa Barbara, CA (US)

(73) Assignee: FREEDOM PHOTONICS, LLC, Santa Barbara, CA (US)

(21) Appl. No.: 13/622,344

(22) Filed: Sep. 18, 2012

Related U.S. Application Data
(60) Provisional application No. 61/537,005, filed on Sep. 20, 2011.

(51) Int. Cl. H01S 5/40

(52) U.S. Cl. CPC H01S 5/40
USPC 372/50.12

(57) ABSTRACT

Various embodiments of an arrangement for generating fast wavelength-switched optical signal are described herein. In some embodiments, the arrangement can be integrated with lasers, optical waveguides, optical splitters and gates to form a fast wavelength switched monolithic optical source. In some embodiments, an optical modulator is incorporated into the arrangement to form a fast wavelength switched optical transmitter.

### CROSS-REFERENCE TO RELATED APPLICATIONS

This application claims the benefit under 35 U.S.C. §119(e) of U.S. Provisional Application 61/537,005 filed on Sep. 20, 2011 titled “Arrangement for Generating Fast Wavelength-Switched Optical Signal,” which is hereby expressly incorporated herein in its entirety.

### STATEMENT REGARDING FEDERALLY SPONSORED R&D

This invention was made with Government support under Contract No. N68335-09-C-0315 awarded by the U.S. Naval Air Systems Command. The Government has certain rights in the invention.

### BACKGROUND

1. Field of the Invention

The embodiments described herein generally relate to wavelength tunable optical sources used for fiber optic, satellite and terrestrial communications and sensing applications, and coherent receivers with monolithically integrated tunable local oscillator light sources.

2. Description of the Related Art

Several applications require optical sources which have fast and accurate adjustment of the operating wavelength. One example is wavelength switched optical sources for use for optical packet switching applications. In this application, modulated optical data bits are grouped together in packets and each packet is encoded on one of many wavelength channels. For the optical source, a wavelength tuning speed lower than typically 10 ns is required to change wavelength between optical packets. Required wavelength accuracy is limited by the requirements of the wavelength division multiplexing (WDM) architecture used and can in some cases be on the order of a few GHz.

Laser wavelength switching speed is limited by several factors. For a semiconductor laser source, the fundamental limit to switching speed is laser resonance, typically <1 ns. Efficient wavelength tuning is often achieved by implementing index tuning in the laser cavity. For example, index tuning through carrier injection into semiconductor optical waveguides has a typical time constant of around 10 ns. Thermal effects will also affect the index in the laser cavity, with time constants in the microsecond to millisecond range. Typically, wavelength tuning occurs due to a combination of several of these effects. As a consequence, the wavelength accuracy and switching speed are inversely related. No current optical sources meets the stringent demands for optical packet switching of a few GHz wavelength accuracy at <10 ns switching speed.

### SUMMARY

Various embodiments of an arrangement for generating fast wavelength-switched optical signal are described herein. The scheme involves at least two optical sources and an arrangement to connect each of the optical sources to a common output port. The wavelength tuning range of the two lasers can overlap. The wavelength tuning range can also not overlap such that the total wavelength tuning range of the source is greater than that of a single laser. In one typical mode of operation, the active laser is followed by an optical gate configured for transmission and is kept at a stable origin operation wavelength. The second, inactive laser is followed by an optical gate which is closed and is allowed to be set and stabilize at a destination wavelength. Wavelength switching is then performed through rapidly closing the transmitting gate, at the same time as the closed gate is opened for transmission, switching the output wavelength of the source from the origin wavelength to the destination wavelength. This arrangement allows the inherent limitations in tuning speed and accuracy of a single source to be overcome by allowing fast optical gates to switch between two stable lasing wavelengths. In some embodiments, the arrangement can be integrated with lasers, optical waveguides, optical splitters and optical gates to form a fast wavelength switched integrated optical source. In some embodiments, an optical modulator is incorporated into the arrangement to form a fast wavelength switched optical transmitter arrangement. In some embodiments, the arrangement is integrated on a single substrate, forming a monolithically integrated fast switched optical source.

### BRIEF DESCRIPTION OF THE DRAWINGS

FIG. 1 illustrates an embodiment of the fast switched optical source incorporating two lasers, and an arrangement for selectively connect the output from one laser to a common output port.

FIG. 2 illustrates output wavelength and optical power as a function of time for the output from each of the optical gates, and for the combined output.

FIG. 3 illustrates an embodiment of the fast switched optical source incorporating two lasers, two optical gates and an arrangement to connect each of the outputs from the optical gates to a common optical output port.

FIG. 4 illustrates an embodiment of the fast switched optical source incorporating two lasers, two optical gates and an arrangement to connect each of the outputs from the optical gates to a common optical output port and an optical modulator at the common output port.

FIG. 5 illustrates an embodiment of the fast switched optical source incorporating two lasers, two optical gates and an arrangement to connect each of the outputs from the optical gates to a common optical output port and an optical Mach-Zehnder modulator at the common output port.

These and other features will now be described with reference to the drawings summarized above. The drawings and the associated descriptions are provided to illustrate embodiments and not to limit the scope of the disclosure or claims. Throughout the drawings, reference numbers may be reused to indicate correspondence between referenced elements. In addition, where applicable, the first one or two digits of a reference numeral for an element can frequently indicate the figure number in which the element first appears.

### DETAILED DESCRIPTION OF THE PREFERRED EMBODIMENT

Although certain preferred embodiments and examples are disclosed below, inventive subject matter extends beyond the specifically disclosed embodiments to other alternative embodiments and/or uses and to modifications and equivalents thereof. Thus, the scope of the claims appended hereto is not limited by any of the particular embodiments described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain embodiments; however, the order of description should not be construed to imply that these operations are order dependent. Additionally, the structures, systems, and/or devices described herein may be embodied using a variety of techniques including techniques that may not be described herein but are known to a person having ordinary skill in the art. For purposes of comparing various embodiments, certain aspects and advantages of these embodiments are described. Not necessarily all such aspects or advantages are achieved by any particular embodiment. Thus, for example, various embodiments may be carried out in a manner that achieves or optimizes one advantage or group of advantages as taught herein without necessarily achieving other aspects or advantages as may also be taught or suggested herein. It will be understood that when an element or component is referred to herein as being “connected” or “coupled” to another element, it can be directly connected or coupled to the other element or intervening elements may be present therebetween.

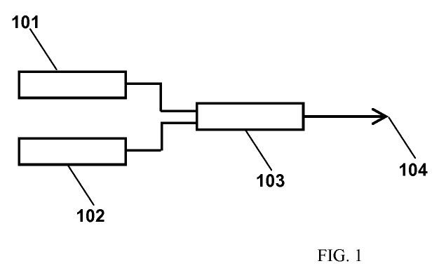

FIG. 1 schematically illustrates an embodiment of an optical transmitter device. The device comprises at least one monocrystalline substrate 101, a laser resonator 102, one or more optical vector modulators 106a and 106b, a polarization rotator 121 and an optical coupler 123. In various embodiments, the various sub-components of the optical transmitter may be monolithically integrated with the substrate 101. The optical vector modulators 106a and 106b may include an input waveguide optically connected to the laser resonator 102, an optical splitter 107, modulation electrode 109 and an output waveguide. These subcomponents and other details are provided below. FIG. 1 illustrates the base arrangement of a fast wavelength switched optical source. The embodiment of a device, illustrated in FIG. 1, comprises a first laser 101, laser #1 and a second laser 102, laser #2. Both laser outputs are connected to an arrangement 103 that can preferentially select the output from any of the two input ports to form the optical output signal at a common output port 104. Laser #1 101 and laser #2 102 can be single wavelength lasers or wavelength tunable lasers. If these lasers are wavelength tunable, the tuning range of the first and second laser can overlap such that the total tuning range of the optical source is equal to that of a single laser. The tuning range of the first and second laser can also only partly overlap or not overlap such that the total tuning range of the optical source is greater than that of a single laser.

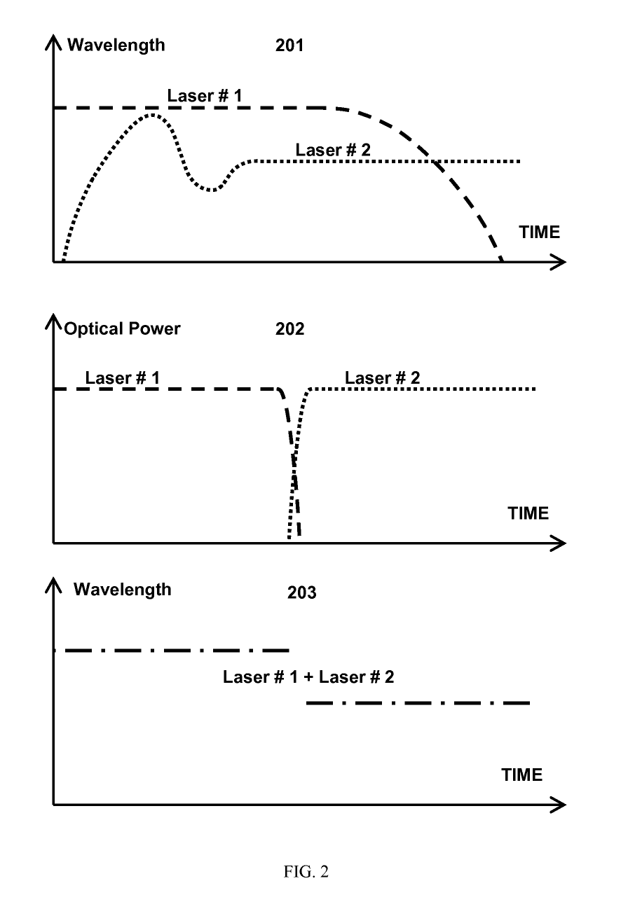

FIG. 2 illustrates one operation example of the fast wavelength switched optical source. The top graph 201 represents the lasing wavelength of laser #1 101 and laser #2 102 as a function of time. Laser #1 is initially set to a stable origin wavelength while laser #2 is allowed to stabilize at the destination wavelength. Once laser #2 has reached a stable lasing wavelength and once after a wavelength switching even, laser #1 is allowed to deviate from its origin wavelength. The center plot 202 represents the optical power of laser #1 and laser# 2 coupled to the common output port 104 as a function of time. At a switching event, the output power from laser #1 is diverted from the output port, while the output from laser #2 is routed to the output port. The lower plot 203 represents the resulting wavelength observed at the common output port 104 as a function of time. The output wavelength is changed from the stabilized origin wavelength of laser #1 to the stabilized destination wavelength of laser #2 in the duration of a switching event.

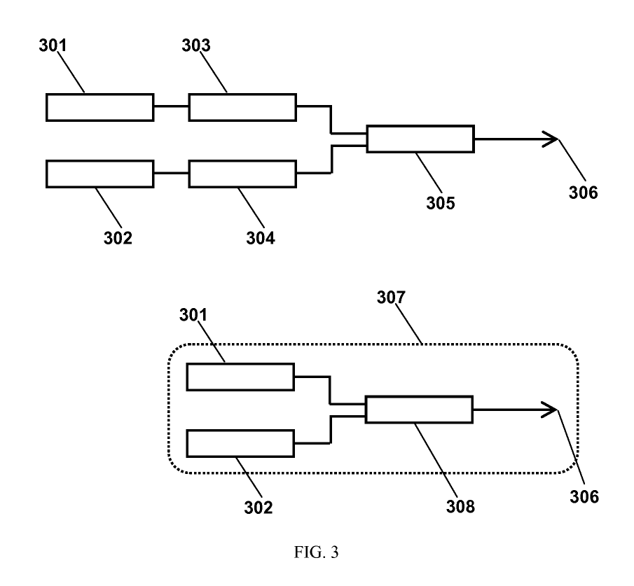

FIG. 3 illustrates an embodiment of a fast wavelength switched optical source. The embodiment of a device, illustrated in FIG. 3, comprises a first laser 301 lasing at a first optical wavelength and a second laser 302 lasing at a second optical wavelength. These lasers can be wavelength tunable. Each of the lasers is followed by an optical gate, 303 and 304. The function of these optical gates is to block the output from the laser if desired. The speed of which the optical gate can be opened up for optical transmission or be closed to block the output from the laser is in a typical embodiment faster that the speed one laser can be adjusted in wavelength from original wavelength to destination wavelength with sufficient accuracy. Examples of optical gate implementations include semiconductor amplifiers, electroabsorption modulators or Mach-Zehnder modulators. The outputs from the optical gates are connected 305 to a single optical output port 306. The connection 305 can consist of a 2×1 or 2×2 optical combiner resulting in an at least 3-dB optical loss, such as a multimode interference coupler, or an arrangement with equivalent functionality. The connection 305 can also be implemented as an active optical switch, allowing the output of one laser to be connected to the common output port with less than 3 dB of optical loss. The active switch can be implemented as a 2×1 or 2×2 Mach-Zehnder interferometer or any other arrangement of equivalent function. In this variation, the active switch must be controlled in a synchronized manner with the optical gates to perform the global wavelength switching function of the present embodiment. One variation of the embodiment of FIG. 3 is shown by the alternative arrangement 307 where the functions of the optical gates 303 and 304, and the connection 305 are combined in a single component 308. This can be a 2×1 or 2×2 Mach-Zehnder interferometer or equivalent arrangement where the desired optical input signal can be routed to the common output port 306 while suppressing other input optical signals.

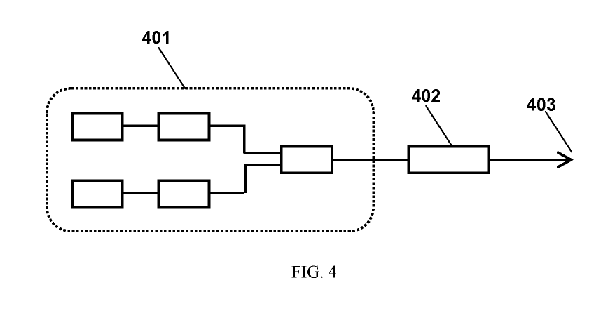

FIG. 4 illustrates a further embodiment of the fast wavelength switched optical source. In this embodiment, the base arrangement of FIG. 3, 401 is connected to a common optical modulator 402, capable of changing the phase and/or amplitude of the common optical output signal. The modulator can be an electroabsorption modulator, a Mach-Zehnder modulator or any other modulator structure capable of performing this function. The optical output signal from the modulator 402 then forms the optical output port 403 from the fast wavelength switched optical source.

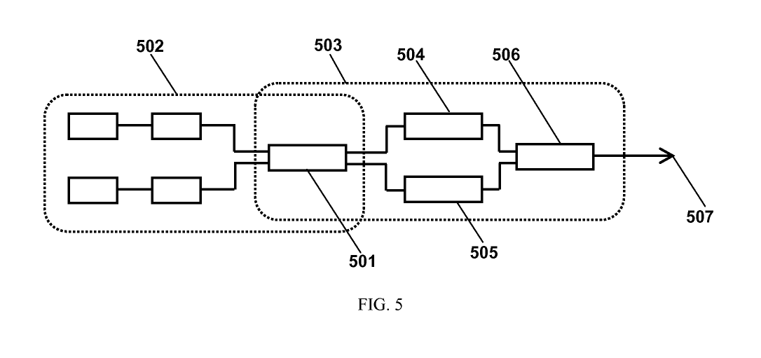

FIG. 5 illustrated a variation embodiment of the fast wavelength switched optical source. In this variation the optical combiner 501 forming part of the base source configuration 502 illustrated in FIG. 3 is a 2×2 type optical coupler which also forms part of a modulator arrangement 503. In this, the two output ports from the 2×2 coupler 501 are each connected to a modulator section 504 and 505 that each modulates optical phase and/or amplitude. These can either be single electrodes, or take the form of a Mach-Zehnder interferometer. The output ports from the two modulators 504 and 505 are combined 506 to form a single common output port 507.

In the above described embodiments, the fast wavelength switched source can be assembled by discrete components such as packaged semiconductor lasers, packaged semiconductor optical amplifiers and fused fiber couplers. The fast wavelength switched source can also comprise one or more epitaxial structures formed on a common monocrystalline substrate. In various embodiments, the monocrystalline substrate 101 may comprise a single epitaxial structure. Without subscribing to any particular theory, a single epitaxial structure refers to a method of depositing a monocrystalline film on a monocrystalline substrate. In various embodiments, epitaxial films may be grown from gaseous or liquid precursors. Because the substrate acts as a seed crystal, the deposited film takes on a lattice structure and orientation identical to those of the substrate. In various embodiments, the epitaxial structure comprises InGaAsP/InGaAs or InAlGaAs layers on either a GaAs or InP substrate grown with techniques such as MOCVD or Molecular Beam Epitaxy (MBE) or with wafer fusion of an active III-V material to a silicon-on-insulator (SOI) material.

As discussed above in various embodiments, the laser resonators 101 and 102 may be formed on the common substrate and/or on the epitaxial structure. In various embodiments, the laser resonator can include a widely tunable laser. In various embodiments, the widely tunable laser can comprise a lasing cavity disposed between two mirrors or reflectors and a tuning section. The optical radiation or laser light generated by the widely tunable laser is output from the reflector disposed closer to the output side of the laser cavity along an optical axis. Without any loss of generality, the reflector through which laser light or optical radiation is emitted is referred to as the output reflector through-out this description. In various embodiments of the optical transmitter device can be aligned parallel to the crystallographic axis of the monocrystalline substrate 101.

In some embodiments, an optical amplifier sections 303 and 304 can be integrated at an output side of the tunable lasers 301 and 302. The optical amplifier sections 303 and 304 can amplify the optical radiation emitted from the laser resonators 301 and 302 and in some embodiments, the optical amplifier sections 303 and 304 may be used to control the power of the generated laser light.

In various embodiments, the optical radiation from the laser resonators 101 and 102 can be combined into a single waveguide using an optical combiner 103. In various embodiments, the optical combiner 103 can include a multimode interference (MMI) splitter. In various embodiments, the optical combiner 103 can comprise at least two input waveguides and at least one output waveguide configured such that optical radiation propagating through the at least one input waveguide is coupled to the at least one output waveguide. In general, integrating a tunable laser with one or more vector modulators on the same chip may require mitigation of light reflection. To this effect, in various embodiments, optical splitters and optical couplers can comprise N inputs and N outputs that can allow for light evacuation and absorption from the vector optical modulators when they are in their unbiased or OFF state. In various embodiments, the combiner 103 can split the light either equally or unequally between the at least two output waveguides. In some embodiments, the optical power splitting ratio between the at least two output waveguide can be tunable.

In some embodiments the optical signal from the combiner 103 or 305 provides an input to a separate optical modulator 402. Without subscribing to any particular theory, an optical modulator may be generally referred to as an optical modulator capable of modulating either optical intensity and/or optical phase of an input optical radiation to generate optical modulation.

In some embodiments, the optical modulator 402 may include an Electro-Absorption modulator (EAM). In various embodiments, the optical modulator 402 may comprise a multi branch structure comprising multiple waveguides. In some embodiments, the optical modulator 402 may include a Mach-Zehnder modulator (MZM). In some embodiments, the optical modulator 402 may include a nested dual Mach-Zehnder modulator. In various embodiments, the optical modulator can be configured to have low optical transmission in their unbiased or OFF state (i.e. when no bias voltages are applied). In some embodiments, this could be accomplished by varying the width and the lengths of the waveguides associated with the optical vector modulators or other methods of refractive index variation between the branches of the optical vector modulators.

What is claimed is:

1. A fast wavelength switched optical source comprising:
At least one monolithic substrate
An in-plane semiconductor laser monolithically integrated with the substrate, said laser being fixed wavelength or tunable, and configured to emit optical radiation from the output reflector along an optical axis
A second in-plane semiconductor laser monolithically integrated with the substrate, said laser being fixed wavelength or tunable, and configured to emit optical radiation from the output reflector along an optical axis
An optical combiner element monolithically integrated with the substrate, with at least 2 input ports and at least 1 output port, where at least 2 input ports are connected to the first and second laser, and where the signal from the first and the second laser are guided to on one or more of the common output ports

2. The wavelength switched optical source from claim 1, where the optical combiner element is an active switch

3. The wavelength switched optical source from claim 1, where at least one of the lasers has an optical gate monolithically integrated along the optical axis between the laser and the optical combiner input port.

4. The wavelength switched optical source from claim 1, where at least one of the lasers has an optical gate monolithically integrated along the optical axis between the laser and the optical combiner input port, and the optical combiner element is an active switch

5. The wavelength switched optical source from claim 1, 2, 3 or 4, where one output of the combiner/switch is connected to an optical intensity modulator

6. The wavelength switched optical source from claim 1, 2, 3 or 4, where one output of the combiner/switch is connected to an optical phase modulator

7. The wavelength switched optical source from claim 1, 2, 3 or 4, where two output ports of the combiner/switch each are connected to a second combiner/switch with at least two input ports, with at least one output port, and where at least one of the waveguides connecting said first combiner/switch to said second combiner/switch contains an optical phase shifter or an optical phase modulator section.
